(19) United States
(12) Patent Application Publication
(10) Pub. No.: US 2026/0075944 A1
(43) Pub. Date: Mar. 12, 2026

(54) ARRAY SUBSTRATE AND DISPLAY PANEL

(71) Applicant: Guangzhou China Star Optoelectronics Semiconductor Display Technology Co., LTd., Guangzhou (CN)

(72) Inventor: Jia TANG, Guangzhou (CN)

(73) Assignee: Guangzhou China Star Optoelectronics Semiconductor Display Technology Co., LTd., Guangzhou (CN)

(21) Appl. No.: 19/091,667

(22) Filed: Mar. 26, 2025

(30) Foreign Application Priority Data
Sep. 6, 2024 (CN) 202411253220.5

(51) Int. Cl. H10D 86/40

(52) U.S. Cl. CPC H10D 86/441; H10D 86/451; H10D 86/423

(57) ABSTRACT

An array substrate includes: a substrate; a first conductive layer including a source and a light-shielding electrode; a second conductive layer including a blocking electrode connected to the source; a first insulating layer being provided with a first via hole opposite to the source; and an oxide active layer including a channel portion and a source contact portion. The channel portion is disposed opposite to the light-shielding electrode. A part of the source contact portion is disposed in the first via hole and connected to the blocking electrode. The blocking electrode is disposed between the source contact portion and the source to block metal elements in the source from diffusing toward the source contact portion.

### CROSS-REFERENCE TO RELATED APPLICATION

This application claims priority to Chinese Patent Application No. 202411253220.5, filed on Sep. 6, 2024. The disclosure of the abovementioned application is incorporated herein by reference in its entirety.

### TECHNICAL FIELD

The present application relates to display technologies, and in particular to an array substrate and a display panel.

### BACKGROUND

As an important component of a display panel, an array substrate with a thin film transistor (TFT) can be manufactured using multiple masks. The more masks are used, the longer the overall flow of a process of manufacturing the array substrate, the more difficult the process is and the higher the cost of the process is. In order to reduce the number of masks to be used in the process, a source of the TFT can be disposed below an oxide active layer, so that the oxide active layer overlaps the source, which however may cause the performance of the TFT device to degrade, thereby affecting the device characteristics and bias temperature stress (BTS) characteristics.

### SUMMARY

According to one or more embodiments of the present application, an array substrate includes a substrate, a first conductive layer, a second conductive layer, a first insulating layer, an oxide active layer, a second insulating layer and a third conductive layer. The first conductive layer is disposed on the substrate, and includes a source and a light-shielding electrode spaced apart from the source. The second conductive layer is disposed on a side of the first conductive layer away from the substrate and includes a blocking electrode connected to the source. The first insulating layer is disposed on the side of the first conductive layer away from the substrate and provided with a first via hole disposed opposite to the source. The oxide active layer is disposed on a side of the first insulating layer away from the substrate and includes a channel portion and a source contact portion on a side of the channel portion. The second insulating layer is disposed, on a side of the oxide active layer away from the substrate, to be opposite to the channel portion. The third conductive layer is disposed on a side of the second insulating layer away from the substrate and includes a gate disposed opposite to the channel portion. The channel portion is disposed opposite to the light-shielding electrode. A part of the source contact portion is disposed in the first via hole and connected to the blocking electrode. The blocking electrode is disposed between the source contact portion and the source to block metal elements in the source from diffusing toward the source contact portion.

According to one or more embodiments of the present application, a display panel includes the above-mentioned array substrate.

### BRIEF DESCRIPTION OF THE DRAWINGS

FIG. 1 is a schematic cross-sectional view of a structure of an array substrate in the related art.

FIG. 2 is a schematic cross-sectional view of a first structure of an array substrate according to one or more embodiments of the present application.

FIG. 3 is a schematic cross-sectional view of a second structure of an array substrate according to one or more embodiments of the present application.

FIG. 4 a schematic cross-sectional view of a third structure of an array substrate according to one or more embodiments of the present application.

FIG. 5 a schematic cross-sectional view of a fourth structure of an array substrate according to one or more embodiments of the present application.

FIG. 6 a schematic block diagram of a display panel including an array substrate according to one or more embodiments of the present application.

### DETAILED DESCRIPTION

Some embodiments of the present application will be described in detail below with reference to the accompanying drawings. The embodiments are described for illustrative purposes only and are not intended to limit the present application.

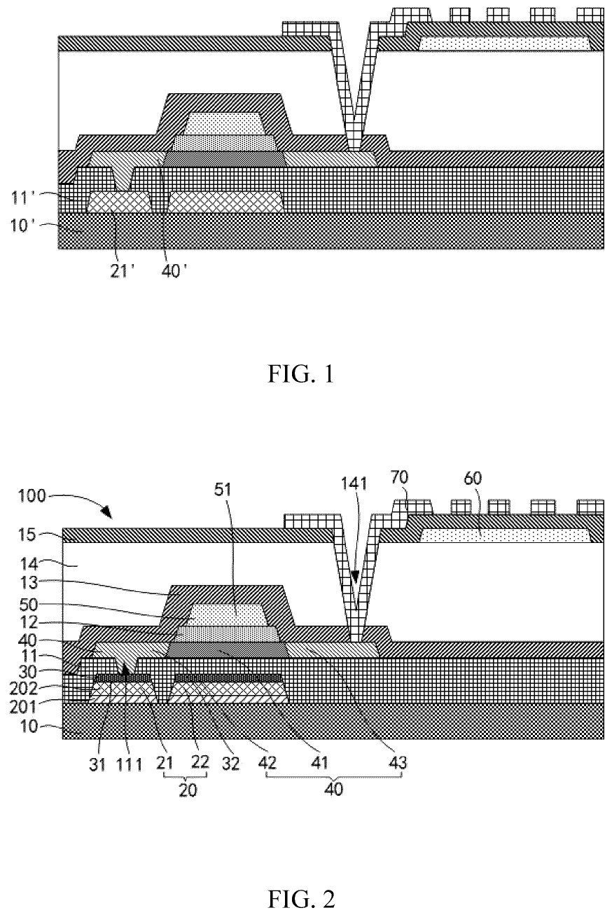

As shown in FIG. 1, an array substrate in the related art includes a substrate 10′ and a first insulating layer 11′, a source electrode 21′, and an oxide active layer 40′ which are disposed on the substrate 10′. Part of the oxide active layer 40′ is disposed in a first via hole of the first insulating layer 11′ and overlaps with the source 21′. The material of the source 21′ is copper. Compared with aluminum, copper has a lower resistivity. However, copper is easy to diffuse and easily causes copper contamination. At the position where the oxide active layer 40′ and the source 21′ are in direct contact, the copper metal element of the source 21′ will diffuse into the oxide active layer 40′ to form deep energy level impurities in the oxide active layer 40′, resulting in the performance degradation of the TFT device, thereby affecting the device characteristics and the bias temperature stress (BTS) characteristics.

In view of this, array substrates and display panels according to some embodiments of the present application are provided.

FIG. 2 is a schematic cross-sectional view of a first structure of an array substrate 100 according to one or more embodiments of the present application. The array substrate 100 includes a substrate 10 and a first conductive layer 20, a second conductive layer 30, a first insulating layer 11, an oxide active layer 40, a second insulating layer 12, and a third conductive layer 50 which are disposed on the substrate 10. The first conductive layer 20 is disposed on the substrate 10 and includes a source electrode 21 and a light-shielding electrode 22 spaced apart from the source. The second conductive layer 30 is disposed on a side of the first conductive layer 20 away from the substrate 10 and includes a blocking electrode 31 connected to the source electrode 21. The first insulating layer 11 is disposed on the side of the first conductive layer 20 away from the substrate 10 and includes a first via hole 111 disposed opposite to the source electrode 21.

The oxide active layer 40 is disposed on a side of the first insulating layer 11 away from the substrate 10 and includes a channel portion 41 and a source contact portion 42 disposed on a side of the channel portion 41. In the thickness direction of the array substrate 100, the channel portion 41 is disposed opposite to the light-shielding electrode 22. It should be noted that “being disposed opposite to” in the present application refers to the opposite relationship between two structures in the thickness direction of the array substrate 100. The material of the oxide active layer can be indium gallium zinc oxide (IGZO), indium gallium zinc tin oxide (IGZTO), indium gallium oxide (IGO), indium zinc oxide (IZO), lanthanide (IZO), etc.

Part of the source contact portion 42 is disposed in the first via hole 111 and connected to the blocking electrode 31. The blocking electrode 31 is connected between the source contact portion 42 and the source 21 and is disposed opposite to the first via hole 111, so that the source contact portion 42 is electrically connected to the source 21 through the blocking electrode 31. The blocking electrode 31 is configured to block the metal elements in the source 21 from diffusing into the source contact portion 42.

It should be noted that the connection described in the present application, which is different from the electrical connection, refers to a direct contact between two structures, while the electrical connection refers to a conduction between two structures through one or more other structures. For example, a connection between the source contact portion 42 and the blocking electrode 31 means that the source contact portion 42 is in direct contact with the blocking electrode 31, while an electrical connection between the source contact portion 42 and the source 21 means that the source contact portion 42 is conductively connected to the source 21 through the blocking electrode 31, but there is no direct contact between the source contact portion 42 and the source 21.

The second insulating layer 12 is disposed on a side of the oxide active layer 40 away from the substrate 10, and in the thickness direction of the array substrate 100, the second insulating layer 12 is disposed opposite to the channel portion 41. The third conductive layer 50 is disposed on a side of the second insulating layer 12 away from the substrate 10, and the third conductive layer 50 includes a gate 51 disposed opposite to the channel portion 41.

In this embodiment, the source contact portion 42 is electrically connected to the source 21 through the blocking electrode 31 to avoid direct contact between the source contact portion 42 and the source 21, and the blocking electrode 31 can block metal elements in the source 21 from diffusing toward the source contact portion 42, so as to avoid the metal elements in the source 21 from diffusing into the oxide active layer 40 to form deep energy level impurities, which will cause degradation of device performance and affect device characteristics and BTS characteristics, and thus improve device stability.

Specifically, the array substrate 100 further includes a first transistor disposed on the substrate 10. The first transistor may be a thin film transistor. The first transistor includes a source 21, an oxide active layer 40, and a gate 51. The oxide active layer 40 is disposed on a side of the source 21 away from the substrate 10, and the gate 51 is disposed on a side of the oxide active layer 40 away from the substrate 10. The oxide active layer 40 includes a channel portion 41 and a source contact portion 42 disposed on a side of the channel portion 41. The oxide active layer 40 further includes a drain contact portion 43 disposed on a side of the channel portion 41 away from the source contact portion 42, that is, the drain contact portion 43 and the source contact portion 42 are disposed on opposite sides of the channel portion 41. The gate 51 is disposed opposite to the channel portion 41, and the orthographic projection of the gate 51 on the substrate 10 overlaps the orthographic projection of the channel portion 41 on the substrate 10.

Optionally, the substrate 10 may be a rigid substrate or a flexible substrate. When the substrate 10 is a rigid substrate, it may include a rigid substrate such as a glass substrate, a quartz substrate or a silicon wafer; when the substrate 10 is a flexible substrate, it may include a flexible substrate such as a polyimide (PI) film or an ultra-thin glass film. When the substrate 10 is a polyimide film, moisture or oxygen may more easily penetrate into the substrate 10 comparing with a glass substrate. To prevent this, a buffer layer having a single-layer or multi-layer structure including silicon oxide or silicon nitride may be disposed on the substrate 10.

The first conductive layer 20 is disposed on the substrate 10 and includes a source 21 and a light-shielding electrode 22 that are spaced and insulated from each other. The light-shielding electrode 22 is at least disposed opposite to the channel portion 41 to shield the channel portion 41 from light, thus reducing the photogenerated leakage current of the first transistor. The first conductive layer 20 includes a bonding layer 201 and a main conductive layer 202 disposed on a side of the bonding layer 201 away from the substrate 10, that is, the source electrode 21 and the light-shielding electrode 22 both include the bonding layer 201 and the main conductive layer 202.

The thickness of the main conductive layer 202 is greater than the thickness of the bonding layer 201. The material of the bonding layer 201 includes one of molybdenum, titanium, and molybdenum-titanium alloy, and the material of the main conductive layer 202 includes copper. Copper has poor adhesion and is difficult to directly bond with a glass substrate or a silicon oxide substrate. By providing the bonding layer 201 in the first conductive layer 20, the adhesion between the main conductive layer 202 and the substrate 10 can be enhanced, and the copper metal element in the main conductive layer 202 can be prevented from diffusing toward the substrate 10 to avoid contaminating the substrate 10.

The second conductive layer 30 is disposed on a side of the first conductive layer 20 away from the substrate 10. A blocking electrode 31 disposed opposite to the source 21 is formed by the second conductive layer 30. The blocking electrode 31 covers the surface of the source 21 away from the substrate 10.

For ease of description, the surface of each structure away from the substrate 10 is defined as the upper surface in the present application, the surface opposite to the upper surface as the lower surface, and the side surfaces connecting the upper surface and the lower surface are sidewall. For example, the surface of the source 21 away from the substrate 10 is the upper surface of the source 21, the surface opposite to the upper surface of the source 21 is the lower surface of the source 21, the lower surface of the source 21 is in contact with the substrate 10, and the side surfaces connecting the upper and lower surfaces of the source 21 are the sidewalls of the source 21. For another example, the surface of the blocking electrode 31 away from the substrate 10 is the upper surface of the blocking electrode 31, the surface opposite to the upper surface of the blocking electrode 31 is the lower surface of the blocking electrode 31, the lower surface of the blocking electrode 31 is in contact with the source 21, and the side surfaces connecting the upper and lower surfaces of the blocking electrode 31 are the sidewalls of the blocking electrode 31. The orthographic projection of the blocking electrode 31 on the substrate 10 overlaps the orthographic projection of the source 21 on the substrate 10, so that the same mask can be used when forming the blocking electrode 31 and the source electrode 21 by patterning, thereby reducing the number of masks and reducing costs.

The material of the second conductive layer 30 has a diffusion property lower than that of copper and is conductive, for example, the material of the second conductive layer 30 includes one of molybdenum, titanium, molybdenum-titanium alloy, indium tin oxide, etc. The thickness of the second conductive layer 30 is less than the thickness of the first conductive layer 20 and further less than the thickness of the main conductive layer 202. The thickness of the second conductive layer 30 ranges from 100 angstroms to 800 angstroms, for example, 100 angstroms, 200 angstroms, 300 angstroms, 400 angstroms, 500 angstroms, 600 angstroms, 700 angstroms, 800 angstroms, etc. When the thickness of the second conductive layer 30 is less than 100 angstroms, the blocking electrode 31 formed by the second conductive layer 30 has poor performance in blocking the diffusion of the metal elements in the source electrode 21; when the thickness of the second conductive layer 30 is greater than 800 angstroms, it will affect the conductivity of the source electrode 21 and form a serious undulating terrain.

Optionally, the second conductive layer 30 is provided with an auxiliary electrode 32 at a position opposite to the light-shielding electrode 22. The auxiliary electrode 32 covers the surface of the light-shielding electrode 22 away from the substrate 10 to prevent the metal elements in the light-shielding electrode 22 from diffusing toward the first insulating layer 11. The orthographic projection of the auxiliary electrode 32 on the substrate 10 overlaps the orthographic projection of the light-shielding electrode 22 on the substrate 10, so that when forming the auxiliary electrode 32 and the light-shielding electrode 22 by patterning, the same mask can be used, thereby reducing the number of masks and reducing costs.

The first insulating layer 11 covers the second conductive layer 30 and the substrate 10. Specifically, the first insulating layer 11 covers the upper surface and sidewalls of the blocking electrode 31, the sidewalls of the source 21, the upper surface and sidewalls of the auxiliary electrode 32, the sidewalls of the light-shielding electrode 22, the gap between the light-shielding electrode 22 and the source 21, and the substrate 10. The first insulating layer 11 covering the upper surface of the blocking electrode 31 forms a first via hole 111 at a position opposite to the source 21, and the first via hole 111 exposes a portion of the blocking electrode 31, that is, the first insulating layer 11 covers a portion of the blocking electrode 31. The first via hole 111 penetrates the first insulating layer 11 to expose at least a portion of the blocking electrode 31, and the aperture of the first via hole 111 is greater than 2 microns.

The orthographic projection of an opening of the first via hole 111 on a side of the first via hole 111 close to the source electrode 21 on the substrate 10 is located within the orthographic projection of the blocking electrode 31 on the substrate 10. The opening of the first via hole 111 on the side of the first via hole 111 close to the source electrode 21 refers to the opening formed on the lower surface of the first insulating layer 11, and correspondingly, the opening formed on the upper surface of the first insulating layer 11 is away from the source electrode 21. The thickness of the first insulating layer 11 ranges from 3000 angstroms to 5000 angstroms, and the depth of the first via hole 111 is equal to the thickness of the first insulating layer 11, that is, the depth of the first via hole 111 ranges from 3000 angstroms to 5000 angstroms, such as 3000 angstroms, 3500 angstroms, 4000 angstroms, 4500 angstroms, 5000 angstroms, etc. The material of the first insulating layer 11 includes an inorganic material, for example, the first insulating layer 11 may be multiple layers or a single layer of at least one of tetraethyl orthosilicate, silicon nitride, and silicon oxide.

The oxide active layer 40 is disposed on a side of the first insulating layer 11 away from the substrate 10. The source contact portion 42 and the drain contact portion 43 of the oxide active layer 40 are formed by conducting the oxide active layer 40, so that the source contact portion 42 and the drain contact portion 43 of the oxide active layer 40 form a conductor region. The source contact portion 42 is disposed on a portion of the first insulating layer 11 and in the first via hole 111. The source contact portion 42 disposed in the first via hole 111 covers the hole walls of the first via hole 111 and the portion of the blocking electrode 31 exposed by the first via hole 111, so as to be connected to the blocking electrode 31.

Since the orthographic projection of the opening of the first via hole 111 on the side of the first via hole 111 close to the source electrode 21 on the substrate 10 is located within the orthographic projection of the blocking electrode 31 on the substrate 10, the source contact portion 42 disposed in the first via hole 111 is blocked from the source electrode 21 by the blocking electrode 31, so that the source contact portion 42 disposed in the first via hole 111 will not directly contact the source electrode 21. The thickness of the oxide active layer 40 ranges from 100 angstroms to 500 angstroms, such as 100 angstroms, 200 angstroms, 220 angstroms, 250 angstroms, 280 angstroms, 300 angstroms, 350 angstroms, 380 angstroms, 400 angstroms, 500 angstroms, etc.

The second insulating layer 12 is disposed on a side of the oxide active layer 40 away from the substrate 10 and is disposed opposite to the channel portion 41. The material of the second insulating layer 12 includes an inorganic material, for example, the second insulating layer 12 may be multiple layers or a single layer of at least one of tetraethyl orthosilicate, silicon nitride, and silicon oxide.

The third conductive layer 50 is disposed on a side of the second insulating layer 12 away from the substrate 10 and includes a gate 51 of the first transistor, and the gate 51 is disposed opposite to the second insulating layer 12. The third conductive layer 50 can be formed as multiple layers or a single layer of a low-resistance material such as Al, Ti, Mo, Cu, Ni or an alloy thereof, or a material with high corrosion resistance. For example, the third conductive layer 50 can be a triple stack of Ti/Cu/Ti, Ti/Ag/Ti, Ti/Al/Ti or Mo/Al/Mo, or others.

As shown in FIG. 2, the array substrate 100 further includes a third insulating layer 13, a planarization layer 14, a common electrode 60, a fourth insulating layer 15, and a pixel electrode 70. The third insulating layer 13 is disposed on a side of the third conductive layer 50 away from the substrate 10, for example, the third insulating layer 13 covers the upper surface and sidewalls of the gate 51, the sidewalls of the second insulating layer 12, the upper surface and a sidewall of the source contact portion 42, the upper surface and a sidewall of the drain contact portion 43, and part of the first insulating layer 11. The material of the third insulating layer 13 includes an inorganic material, for example, the third insulating layer 13 may be multiple layers or a single layer of at least one of tetraethyl orthosilicate, silicon nitride, and silicon oxide.

The planarization layer 14 is disposed on a side of the third insulating layer 13 away from the substrate 10. The material of the planarization layer 14 includes an organic material, for example, the planarization layer 14 can be formed of a resin, such as polyacrylate or polyimide, a silica-based organic material, or the like.

The common electrode 60 is disposed on a side of the planarization layer 14 away from the substrate 10. The common electrode 60 may be formed of a transparent conductive material such as indium tin oxide (ITO), indium zinc oxide (IZO), zinc oxide (ZnO) or indium oxide (In2O3).

The fourth insulating layer 15 is disposed on a side of the common electrode 60 away from the substrate 10. The fourth insulating layer 15 includes a second via hole 141 disposed opposite to the drain contact portion 43, and the second via hole 141 penetrates the fourth insulating layer 15, the planarization layer 14 and the third insulating layer 13 to expose a portion of the drain contact portion 43. The material of the fourth insulating layer 15 includes an inorganic material, for example, the fourth insulating layer 15 may be multiple layers or a single layer of at least one of tetraethyl orthosilicate, silicon nitride, and silicon oxide.

The second pixel electrode 70 is disposed on a side of the fourth insulating layer 15 away from the substrate 10, and a portion of the pixel electrode 70 is located in the second via hole 141 and connected to the drain contact portion 43 exposed by the second via hole 141. The pixel electrode 70 is disposed opposite to the common electrode 60, and the material of the pixel electrode 70 can be the same as the material of the common electrode 60, for example, the pixel electrode 70 can also be formed of a transparent conductive material such as indium tin oxide (ITO), indium zinc oxide (IZO), zinc oxide (ZnO) or indium oxide (In2O3).

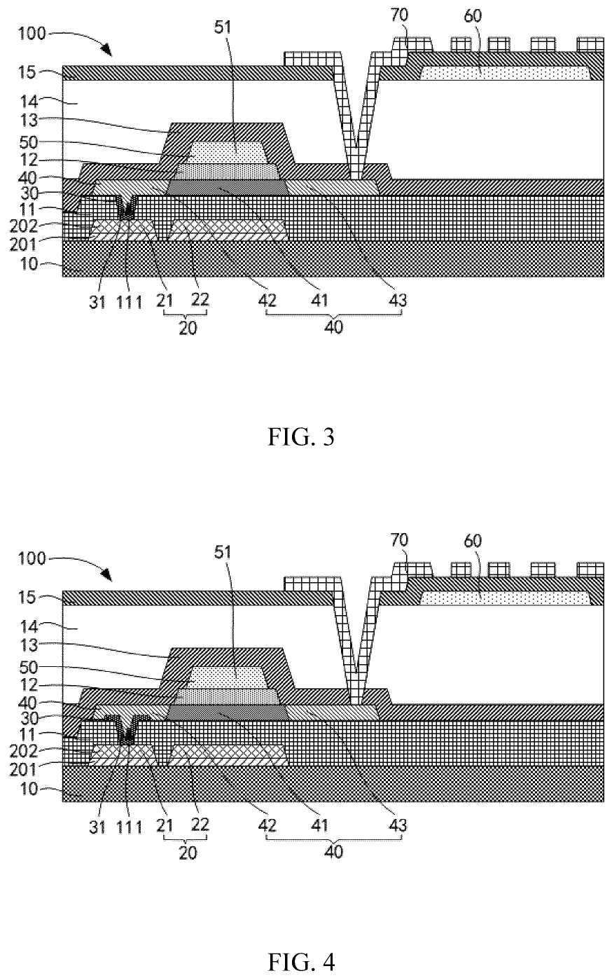

FIG. 3 is a schematic cross-sectional view of a second structure of the array substrate 100 according to one or more embodiments of the present application. As shown in FIG. 3, different from the embodiment corresponding to FIG. 2, the blocking electrode 31 is disposed in the first via hole 111, and the source contact portion 42 covers the blocking electrode 31 in the first via hole 111.

Specifically, the first insulating layer 11 provides the first via hole 111 at a position opposite to the source electrode 21, and the first via hole 111 exposes a portion of the source electrode 21. The blocking electrode 31 is disposed in the first via hole 111 and is exposed by the first via hole 111. The blocking electrode 31 covers the hole wall of the first via hole 111 and the source electrode 21 exposed by the first via hole 111, and is connected to the source electrode 21. A portion of the source contact portion 42 is disposed in the first via hole 111 and covers the blocking electrode 31 in the first via hole 111.

The orthographic projection of the opening of the first via hole 111 on a side of the first via hole 111 close to the source electrode 21 on the substrate 10 is within the orthographic projection of the blocking electrode 31 on the substrate 10, so that the source contact portion 42 disposed in the first via hole 111 is blocked from the source electrode 21 by the blocking electrode 31, thus the source contact portion 42 located in the first via hole 111 will not directly contact the source electrode 21. Moreover, by disposing the blocking electrode 31 in the first via hole 111 and making the source contact portion 42 cover the blocking electrode 31 disposed in the first via hole 111, the contact area between the source contact portion 42 and the blocking electrode 31 can be increased, and the reliability of the electrical connection between the source contact portion 42 and the source electrode 21 can be improved, so that the first via hole 111 with a smaller aperture can achieve a high-reliability electrical connection between the source contact portion 42 and the source electrode 21, thereby reducing the occupied area of the first transistor device.

It should be noted that the thickness of the first insulating layer 11 is relatively large, and the thickness of the oxide active layer 40 is relatively small, and the thickness of the oxide active layer 40 is much smaller than the thickness of the first insulating layer 11. When the aperture of the first via hole 111 is relatively small, due to the relatively large thickness of the first insulating layer 11, the taper angle of the first via hole 111 is relatively large, and the oxide active layer 40 with a relatively small thickness is prone to problems such as disconnection when climbing in the first via hole 111, thereby affecting the reliability of the electrical connection between the source contact portion 42 and the source 21. In order to avoid problems such as disconnection when the oxide active layer 40 climbs in the first via hole 111, the first via hole 111 with a relatively large aperture can be provided, for example, the aperture of the first via hole 111 is greater than 2 microns, but this will increase the occupied area of the first transistor device.

In the present embodiment, by disposing the blocking electrode 31 in the first via hole 111 and making the source contact portion 42 cover the blocking electrode 31 in the first via hole 111, the contact area between the source contact portion 42 and the blocking electrode 31 can be increased. Even if the source contact portion 42 is broken while climbing in the first via hole 111, the blocking electrode 31 can fill the broken part of the source contact portion 42, thereby improving the reliability of the electrical connection between the source contact portion 42 and the source 21. Therefore, a first via hole 111 with a smaller aperture can be provided to achieve a high-reliability electrical connection between the source contact portion 42 and the source 21, thereby reducing the occupied area of the first transistor device.

Optionally, the end of the blocking electrode 31 away from the source electrode 21 is flush with the upper surface of the first insulating layer 11, that is, the boundary of the blocking electrode 31 away from the source electrode 21 is flush with the upper surface of the first insulating layer 11. In other words, the blocking electrode 31 is disposed in the first via hole 111, but does not extend beyond the first via hole 111. In this way, the flatness of the upper surface of the first insulating layer 11 is not affected, which facilitates the preparation of the oxide active layer 40. For other related descriptions, please refer to the above embodiment, which will not be repeated here.

FIG. 4 is a schematic cross-sectional view of a third structure of the array substrate 100 according to one or more embodiments of the present application. As shown in FIG. 4, different from the embodiment corresponding to FIG. 3, the blocking electrode 31 extends from the first via hole 111 to the surface of the first insulating layer 11 away from the substrate 10, and the source contact portion 42 further covers the blocking electrode 31 disposed outside the first via hole 111. That is, the blocking electrode 31 is further disposed on a portion of the upper surface of the first insulating layer 11, so that the contact area between the source contact portion 42 and the blocking electrode 31 can be further increased, thereby further improving the reliability of the electrical connection between the source contact portion 42 and the source 21. Please refer to the above embodiment for other related descriptions, which will not be repeated here.

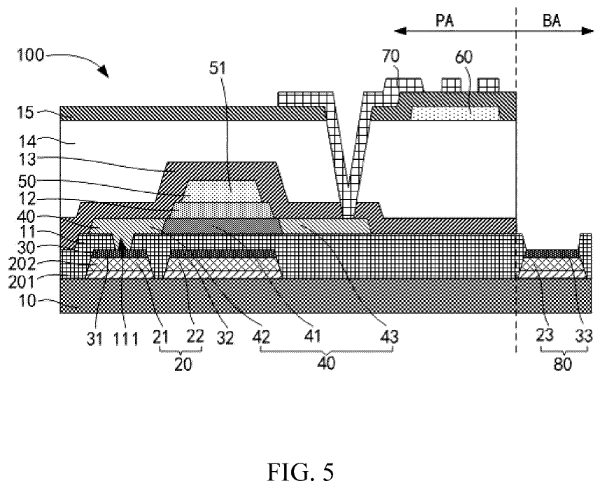

FIG. 5 is a schematic cross-sectional view of a fourth structure of the array substrate 100 according to one or more embodiments of the present application. As shown in FIG. 5, different from the embodiment corresponding to FIG. 2, the array substrate 100 is partitioned into a pixel area PA and a binding area BA disposed on a side of the pixel area PA. The first transistor, the common electrode 60 and the pixel electrode 70 are all disposed in the pixel area PA. The array substrate 100 further includes a binding terminal 80 disposed in the binding area BA, and the binding terminal 80 is used to bind an external driving circuit to provide a signal to the pixel area PA. The first insulating layer 11 provides a third via hole at a position opposite to the binding terminal 80 which exposes the binding terminal 80.

The binding terminal 80 includes a first binding sub-portion 23 and a second binding sub-portion 33 disposed on a side of the first binding sub-portion 23 away from the substrate 10. The first binding sub-portion 23 is formed by the first conductive layer 20, and the second binding sub-portion 33 is formed by the second conductive layer 30, that is, the first conductive layer 20 further includes the first binding sub-portion 23 disposed in the binding area BA, and the second conductive layer 30 further includes the second binding sub-portion 33 disposed in the binding area BA. The first binding sub-portion 23 is disposed in the same layer as the source electrode 21, and the second binding sub-portion 33 is disposed in the same layer as the blocking electrode 31.

The material of the second conductive layer 30 is indium tin oxide which is an oxide and will not be affected by subsequent processes such as oxygen ashing and high temperature, resulting in increased impedance. However, molybdenum, titanium, and molybdenum-titanium alloys are easily affected by subsequent processes such as oxygen ashing and high temperature, resulting in increased impedance. Therefore, when the first conductive layer 20 and the second conductive layer 30 are further used to form the binding terminal 80 of the binding area BA, the material of the second conductive layer 30 is selected as indium tin oxide to avoid affecting the overall impedance of the binding terminal 80. For other related descriptions, please refer to the above embodiments, which will not be repeated here.

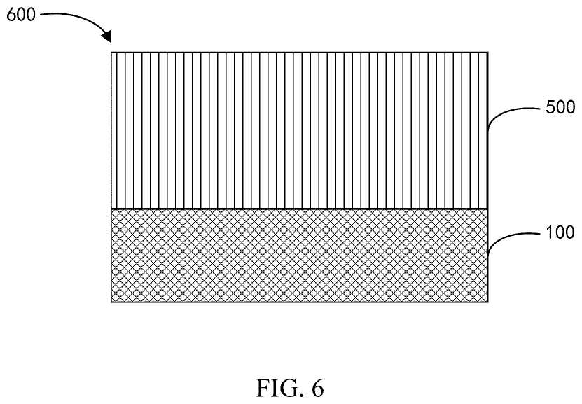

In addition, as shown in FIG. 6, a display panel 600 according to one or more embodiments of the present application includes a display functional layer 500 and the array substrate 100 according to one of the above embodiments. The display panel 600 includes a liquid crystal display panel, an organic light emitting diode display panel or other types of display panels.

Some embodiments of the present application have been described in detail above. The embodiments are described for illustrative purposes only and are not intended to limit the present application. Many modifications or equivalent substitutions with respect to the embodiments may occur to those of ordinary skill in the art based on the present application and thus shall fall within the scope of the present application defined by the appended claims.

What is claimed is:

1. An array substrate, comprising:
a substrate;
a first conductive layer disposed on the substrate, the first conductive layer comprising a source and a light-shielding electrode spaced apart from the source;
a second conductive layer disposed on a side of the first conductive layer away from the substrate, the second conductive layer comprising a blocking electrode connected to the source;
a first insulating layer disposed on the side of the first conductive layer away from the substrate, the first insulating layer being provided with a first via hole opposite to the source;
an oxide active layer disposed on a side of the first insulating layer away from the substrate, the oxide active layer comprising a channel portion and a source contact portion on a side of the channel portion;
a second insulating layer disposed, on a side of the oxide active layer away from the substrate, to be opposite to the channel portion; and
a third conductive layer disposed on a side of the second insulating layer away from the substrate, the third conductive layer comprising a gate disposed opposite to the channel portion,
wherein the channel portion is disposed opposite to the light-shielding electrode;
a part of the source contact portion is disposed in the first via hole and connected to the blocking electrode; and
the blocking electrode is disposed between the source contact portion and the source to block metal elements in the source from diffusing toward the source contact portion.

2. The array substrate according to claim 1, wherein the blocking electrode covers a surface of the source away from the substrate; and
the blocking electrode comprises a first part covered by the first insulating layer, and a second part exposed by the first via hole and connected to the part of the source contact portion.

3. The array substrate according to claim 2, wherein an orthographic projection of the blocking electrode on the substrate overlaps an orthographic projection of the source on the substrate.

4. The array substrate according to claim 2, wherein the second conductive layer further comprises an auxiliary electrode covering a surface of the light-shielding electrode away from the substrate; and
the first insulating layer further covers the auxiliary electrode and a gap between the light-shielding electrode and the source.

5. The array substrate according to claim 1, wherein the first insulating layer covers a first part of the source, the light-shielding electrode, and a gap between the light-shielding electrode and the source;
a second part of the source is exposed by the first via hole; and
at least part of the blocking electrode is disposed in the first via hole, connected to the second part of the source, and covered by the source contact portion.

6. The array substrate according to claim 5, wherein the blocking electrode extends from the first via hole to a surface of the first insulating layer away from the substrate; and
the source contact portion further covers a part of the blocking electrode located outside the first via hole.

7. The array substrate according to claim 1, wherein an orthographic projection of an opening of the first via hole close to the source on the substrate is located within an orthographic projection of the blocking electrode on the substrate.

8. The array substrate according to claim 1, wherein a thickness of the second conductive layer ranges from 100 angstroms to 800 angstroms.

9. The array substrate according to claim 1, wherein a material of the second conductive layer comprises one of molybdenum, titanium, a molybdenum-titanium alloy, and indium tin oxide.

10. The array substrate according to claim 1, wherein the first conductive layer comprises a bonding layer and a main conductive layer disposed on a side of the bonding layer away from the substrate; and
a material of the bonding layer comprises one of molybdenum, titanium, and a molybdenum-titanium alloy, and a material of the main conductive layer comprises copper.

11. The array substrate according to claim 1, wherein the oxide active layer further comprises a drain contact portion disposed on a side of the channel portion away from the source contact portion; and
the array substrate further comprises:
a third insulating layer disposed on a side of the third conductive layer away from the substrate;
a planarization layer disposed on a side of the third insulating layer away from the substrate;
a common electrode disposed on a side of the planarization layer away from the substrate;
a fourth insulating layer disposed on a side of the common electrode away from the substrate;
a second via hole penetrating the fourth insulating layer, the planarization layer and the third insulating layer to expose a part of the drain contact portion; and
a pixel electrode comprising a first part disposed on a side of the fourth insulating layer away from the substrate, and a second part disposed in the second via hole and connected to the drain contact portion.

12. A display panel comprising an array substrate, the array substrate comprising:
a substrate;
a first conductive layer disposed on the substrate, the first conductive layer comprising a source and a light-shielding electrode spaced apart from the source;
a second conductive layer disposed on a side of the first conductive layer away from the substrate, the second conductive layer comprising a blocking electrode connected to the source;
a first insulating layer disposed on the side of the first conductive layer away from the substrate, the first insulating layer being provided with a first via hole opposite to the source;
an oxide active layer disposed on a side of the first insulating layer away from the substrate, the oxide active layer comprising a channel portion and a source contact portion on a side of the channel portion;
a second insulating layer disposed, on a side of the oxide active layer away from the substrate, to be opposite to the channel portion; and
a third conductive layer disposed on a side of the second insulating layer away from the substrate, the third conductive layer comprising a gate disposed opposite to the channel portion,
wherein the channel portion is disposed opposite to the light-shielding electrode;
a part of the source contact portion is disposed in the first via hole and connected to the blocking electrode; and
the blocking electrode is disposed between the source contact portion and the source to block metal elements in the source from diffusing toward the source contact portion.

13. The display panel according to claim 12, wherein the blocking electrode covers a surface of the source away from the substrate; and
the blocking electrode comprises a first part covered by the first insulating layer, and a second part exposed by the first via hole and connected to the part of the source contact portion.

14. The display panel according to claim 13, wherein an orthographic projection of the blocking electrode on the substrate overlaps an orthographic projection of the source on the substrate.

15. The display panel according to claim 13, wherein the second conductive layer further comprises an auxiliary electrode covering a surface of the light-shielding electrode away from the substrate; and
the first insulating layer further covers the auxiliary electrode and a gap between the light-shielding electrode and the source.

16. The display panel according to claim 12, wherein the first insulating layer covers a first part of the source, the light-shielding electrode, and a gap between the light-shielding electrode and the source;
a second part of the source is exposed by the first via hole; and
at least part of the blocking electrode is disposed in the first via hole, connected to the second part of the source, and covered by the source contact portion.

17. The display panel according to claim 16, wherein the blocking electrode extends from the first via hole to a surface of the first insulating layer away from the substrate; and
the source contact portion further covers a part of the blocking electrode located outside the first via hole.

18. The display panel according to claim 12, wherein an orthographic projection of an opening of the first via hole close to the source on the substrate is located within an orthographic projection of the blocking electrode on the substrate.

19. The display panel according to claim 12, wherein a material of the second conductive layer comprises one of molybdenum, titanium, a molybdenum-titanium alloy, and indium tin oxide.

20. The display panel according to claim 12, wherein the first conductive layer comprises a bonding layer and a main conductive layer disposed on a side of the bonding layer away from the substrate; and
a material of the bonding layer comprises one of molybdenum, titanium, and a molybdenum-titanium alloy, and a material of the main conductive layer comprises copper.
